(19) United States
(12) Patent Application Publication
(10) Pub. No.: US 2025/0323041 A1
(43) Pub. Date: Oct. 16, 2025

(54) WAFER SINGULATION INCLUDING MULTIPLE LASER GROOVING

(71) Applicant: Taiwan Semiconductor Manufacturing Co., Ltd., Hsinchu (TW)

(72) Inventors: Hsuan-Ting Kuo, Taichung City (TW); Cheng-Shiuan Wong, Hsinchu (TW); Chia-Shen Cheng, Hsinchu (TW); Hsiu-Jen Lin, Zhubei City (TW)

(21) Appl. No.: 18/777,772

(22) Filed: Jul. 19, 2024

Related U.S. Application Data
(60) Provisional application No. 63/633,109, filed on Apr. 12, 2024.

(51) Int. Cl. H01L 21/268; H01L 21/78; H01L 23/00

(52) U.S. Cl. CPC H01L 21/268; H01L 21/78; H01L 24/08; H01L 2224/08145

(57) ABSTRACT

A method includes performing a first plurality of laser grooving processes on a scribe line of a wafer to form a first combined groove, and performing a second plurality of laser grooving processes on the scribe line of the wafer to form a second combined groove. A first sawing process is performed on the scribe line of the wafer. The first sawing process is performed in a part of the scribe line between the first combined groove and the second combined groove. A second sawing process is performed to saw through the wafer in the scribe line. The second sawing process separates a first device die and a second device die on opposing sides of the scribe line from each other.

### PRIORITY CLAIM AND CROSS-REFERENCE

This application claims the benefit of the following provisionally filed U.S. Patent application: Application No. 63/633,109, filed on Apr. 12, 2024, and entitled “SINGULATION METHOD,” which application is hereby incorporated herein by reference.

### BACKGROUND

The packages of integrated circuits are becoming increasing complex, with more device dies integrated in the same package to achieve more functions. For example, packages may be formed to include a plurality of device dies such as processors and memory cubes in the same package. The packages can include device dies formed using different technologies and have different functions bonded to the same device die, thus forming a system. This may save manufacturing cost and achieve optimized device performance. The packages may be formed as a reconstructed wafer, which is then singulated to form discrete packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8, 9A, 9B, 10A, 10B, 11A, 11B through 15 illustrate the cross-sectional views of intermediate stages in the formation of a reconstructed wafer and the singulation process in accordance with some embodiments.

FIG. 16A illustrates an edge portion of a package in accordance with some embodiments.

FIG. 16B illustrates a top view of a package in accordance with some embodiments.

FIGS. 17 and 18 illustrate the cross-sectional views of intermediate stages in a laser grooving process using a defocusing laser beam in accordance with some embodiments.

FIG. 19 illustrates a package including residue portions in accordance with some embodiments.

FIG. 20 illustrates the edge portion of a package in accordance with some embodiments.

FIG. 21 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, a reconstructed wafer is formed, and then singulated into a plurality of packages. The singulation process may include a plurality of laser grooving processes, wherein the running paths of the laser grooving processes may partially overlap. A wide blade sawing (grooving) process may then be performed to saw through the structure overlapping a semiconductor substrate of the reconstructed wafer, until the semiconductor substrate is exposed. A narrow blade sawing process may then be performed to saw the reconstructed wafer apart into packages.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

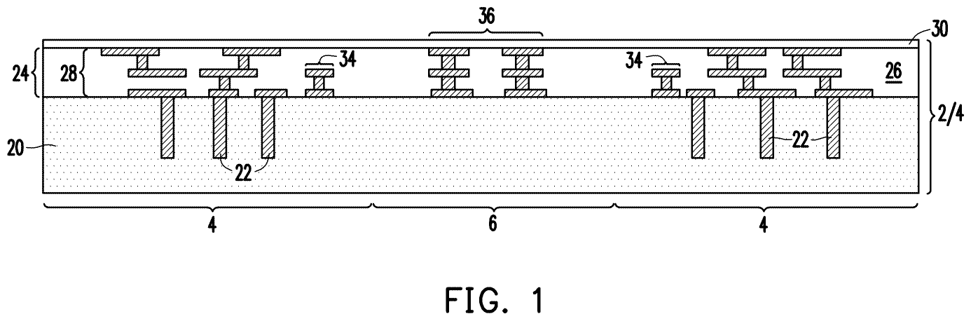

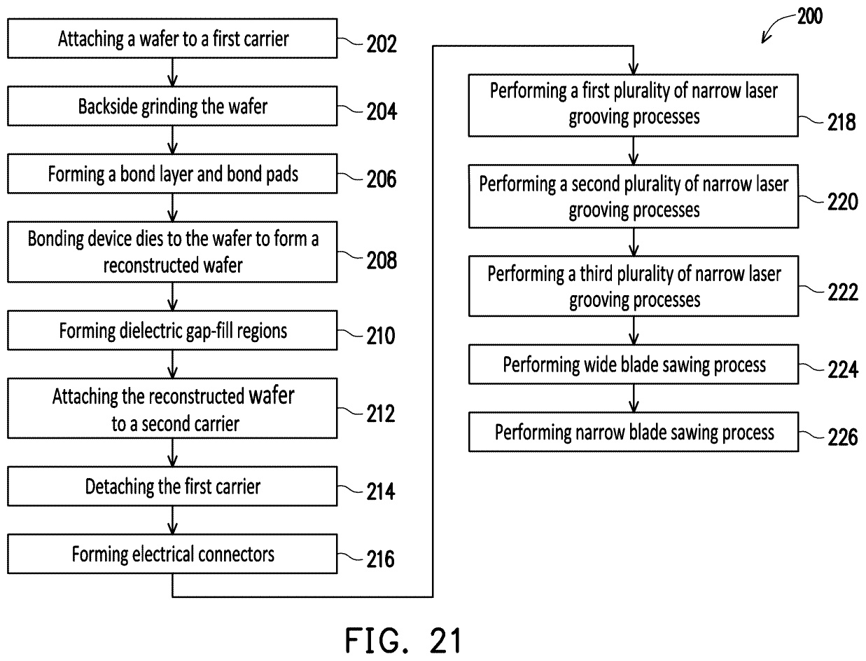

FIGS. 1 through 15 illustrate the cross-sectional views of intermediate stages in the formation of a reconstructed wafer and the singulation process of the reconstructed wafer to form packages in accordance with some embodiments of the present disclosure. The corresponding processes are also reflected schematically in the process flow 200 as shown in FIG. 21.

FIG. 1 illustrates a cross-sectional view of package component 2 in accordance with some embodiments. Package component 2 may include a plurality of device dies 4 therein, with the edge portions of two neighboring device dies 4 illustrated. Device dies 4 are alternatively referred to as chips hereinafter. In accordance with some embodiments, device die 4 is a memory die such as a Dynamic Random-Access Memory (DRAM) die or a Static Random-Access Memory (SRAM) die. Device die 4 may also be a logic die, which may be a Central Processing Unit (CPU) die, a Micro Control Unit (MCU) die, an input-output (IO) die, a BaseBand (BB) die, an Application processor (AP) die, or the like.

In accordance with some embodiments, wafer 2 includes semiconductor substrate 20 and the features formed at a top surface of semiconductor substrate 20. Semiconductor substrate 20 may be formed of crystalline silicon, crystalline germanium, crystalline silicon germanium, or the like. Through-vias 22 (Also referred to Through-Silicon Vias (TSVs)) may be formed to extend into semiconductor substrate 20, and the TSVs 22 are to be used to electrically inter-couple the features on opposite sides of wafer 2.

In accordance with some embodiments, package component 2 is a device wafer including active devices such as transistors and/or diodes, and possibly passive devices such as capacitors, inductors, resistors, or the like. In accordance with some embodiments, the active devices are formed on the top surface of semiconductor substrate 20. Example integrated circuit devices may include Complementary Metal-Oxide Semiconductor (CMOS) transistors, resistors, capacitors, diodes, and/or the like. In accordance with alternative embodiments, wafer 2 is used for forming interposers, which are free from active devices and passive devices.

Interconnect structure 24 is formed over semiconductor substrate 20. In accordance with some embodiments, interconnect structure 24 includes a plurality of dielectric layers 26, and conductive features 28 in the dielectric layers 26. The dielectric layers 26 may include an Inter-Layer Dielectric (ILD) and a plurality of Inter-Metal Dielectric (IMD) layers over the ILD. The ILD may be formed of silicon oxide, Phospho Silicate Glass (PSG), Boro Silicate Glass (BSG), Boron-Doped Phospho Silicate Glass (BPSG), Fluorine-Doped Silicate Glass (FSG), or the like. The IMD layers may be formed of low-k dielectric layers. The dielectric layers 26 may further include non-low-k dielectric layers over the IMD layer.

The conductive features 28 in the dielectric layers 26 may include contact plugs, metal lines, vias, metal pads, and the like. The formation process may include single damascene and dual damascene processes. The materials of the conductive features may include tungsten, aluminum, copper, titanium, tantalum, titanium nitride, tantalum nitride, alloys thereof, and/or multi-layers thereof.

In accordance with some embodiments, seal rings 34 are formed to encircle the inner area (the active areas) of the respective device dies 4. The active areas are used to form functional integrated circuits (active devices and passive devices) and interconnect structures. Seal rings 34 may be formed as full rings, with no breaks therein in the top view. Before wafer 2 is singulated, the outer edges of seal rings 34 may be considered as the outer boundaries of the device dies 4. It is appreciated, however, that the subsequently discussed singulation process will leave some portions of scribe lines 6 outside of the seal rings 34 of the discrete device dies 4. Accordingly, after the singulation process for sawing wafer 2 into discrete device dies 4, the discrete device dies 4 also include some portions outside of the respective seal rings 34.

In accordance with some embodiments, each device die 4 may include a single seal ring. Alternatively, each device die 4 may include a plurality of seal rings, with outer seal ring(s) encircling the respective inner seal ring(s) s. When more than one seal ring is formed for each of device dies 4, the illustrated seal rings 34 is the outmost seal ring that is closest to the scribe lines 6.

In accordance with some embodiments, seal rings 34 include some portions of conductive features 28. For example, seal rings 34 may include metal lines and vias, and may or may not include contact plugs and aluminum pads. Each of the contact plugs and metal lines/vias in seal rings 34 may form a full ring, which is physically joined with the overlying and underlying rings of the conductive features to form an integrated seal ring.

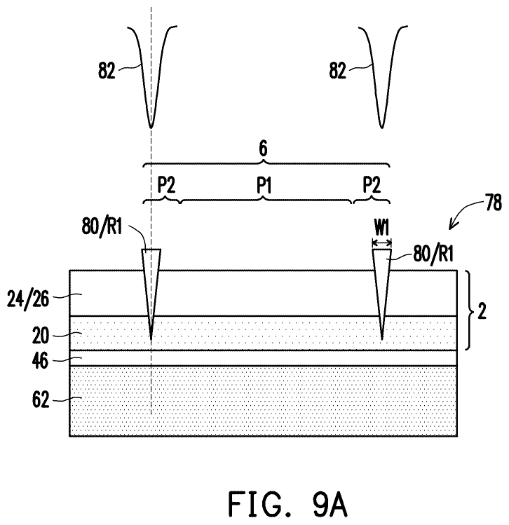

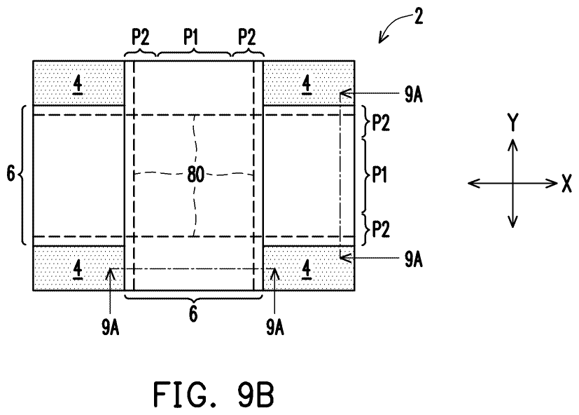

Referring to FIG. 9B, which illustrates a top view of a portion of wafer 2, a plurality of device dies 4 are arranged as an array including a plurality of rows and columns, with four of the device dies 4 being illustrated. A plurality of scribe lines 6 are located in horizontal directions (X-directions) and vertical directions (Y-directions) to separate the rows and the columns of device dies 4.

Referring back to FIG. 1, in accordance with some embodiments, dummy conductive features 36 are formed in scribe line 6, and outside of the seal rings 34 of device dies 4. In accordance with alternative embodiments, no dummy conductive features 36 are formed in scribe line 6. In accordance with some embodiments, dummy conductive features 36 include testing conductive features, which are used for testing the functionality of device dies 4. The testing may be performed by probing conductive pads, which are the top surface features of dummy conductive features 36. The testing is performed before the subsequently discussed singulation process of wafer 2.

In accordance with some embodiments, after the probing process, dielectric layer 30 is formed as a top surface layer of wafer 2. In accordance with alternative embodiments, dielectric layer 30 is not formed. Dielectric layer 30 may be deposited using Plasma-Enhanced Chemical Vapor Deposition (PECVD), Atomic Layer Deposition (ALD), High Density Plasma Chemical Vapor Deposition (HDPCVD), Plasma Enhanced ALD (PECVD), or the like. Dielectric layer 30 may be formed of or comprise a silicon-containing dielectric material. In accordance with some embodiments, the material of dielectric layer 30 may be expressed as SiOₓN_{y}C_{z}, with x, y, z being the relative ratios of O, N, and C. For example, dielectric layer 30 may be formed of or comprises SiON, SiN, SiOCN, SiCN, SiOC, SiC, SiO₂, or the like.

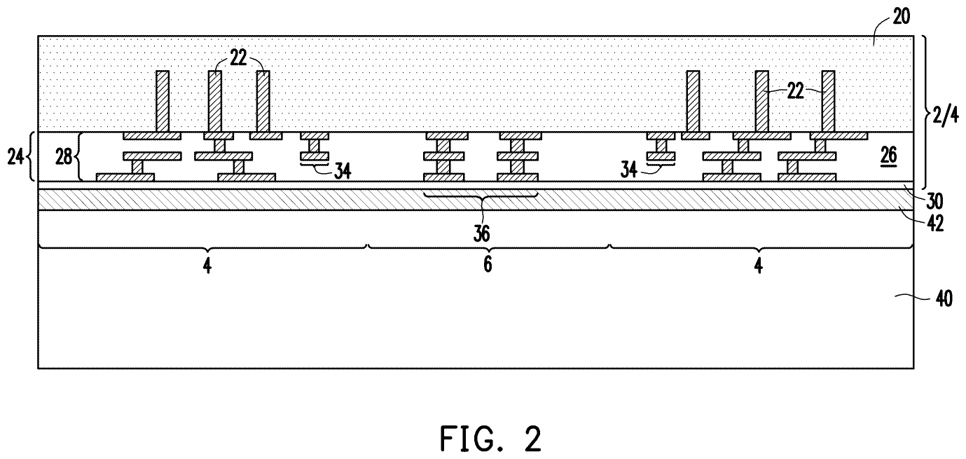

Referring to FIG. 2, the front side of wafer 2 is attached to carrier 40 through layer 42. The respective process is illustrated as process 202 in the process flow 200 as shown in FIG. 21. In accordance with some embodiments, carrier 40 is a semiconductor carrier such as a silicon carrier, and layer 42 is a bond layer. Layer 42, when being the bond layer, may be formed of a silicon-containing dielectric material selected from SiO, SiC, SiN, SiON, SiOC, SiCN, SiOCN, or the like, or combinations thereof. Wafer 2 is accordingly bonded to carrier 40, with bond layer 42 being bonded to layer 30 through fusion bonding in accordance with some embodiments.

In accordance with alternative embodiments, carrier 40 includes a transparent substrate such as a glass substrate, and layer 42 may be formed of an adhesive such as a light-to-heat-Conversion (LTHC) material, which is configured to be decomposed under the heat of light (such as a laser beam) when carrier 40 is de-bonded.

After wafer 2 is attached to carrier 40, a backside grinding process is performed to thin semiconductor substrate 20. The respective process is illustrated as process 204 in the process flow 200 as shown in FIG. 21. In accordance with some embodiments, the planarization process is performed until TSVs 22 are revealed. The semiconductor substrate 20 in device dies 4 may be recessed through an etching process, so that the top portions of TSVs 22 protrude over semiconductor substrate 20. A dielectric isolation layer (not shown) may then be filled into the recesses. The formation of the dielectric isolation layer may include performing a deposition process to deposit a dielectric layer into the recesses, so that the protruding portions of TSVs 22 are in the dielectric layer, followed by a planarization process. The portions of the dielectric layer over TSVs 22 are removed, and the remaining portions of the dielectric layer form the dielectric isolation layer, which becomes parts of wafer 2.

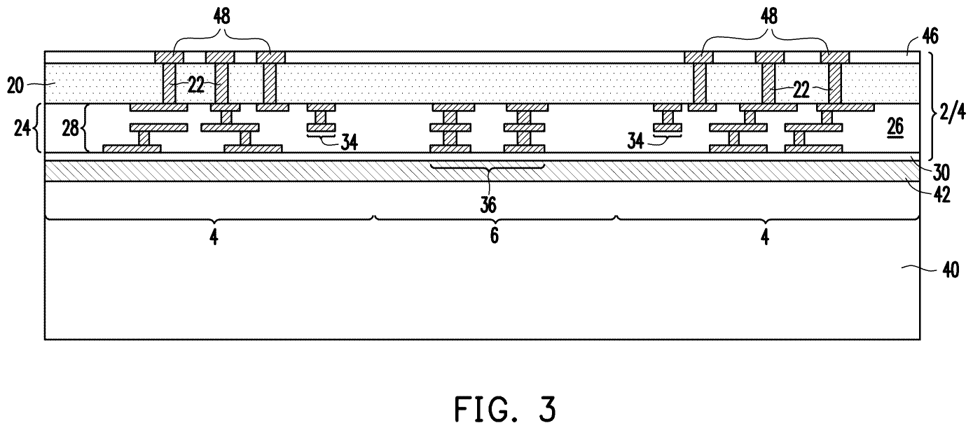

Referring to FIG. 3, bond layer 46 and bond pads 48 are formed. The respective process is illustrated as process 206 in the process flow 200 as shown in FIG. 21. Bond layer 46 is deposited on wafer 2 and through-vias 22. Bond layer 46 may be formed of a silicon-containing dielectric material, which silicon-containing dielectric material may be selected from SiO, SiC, SiN, SiON, SiOC, SiCN, SiOCN, or the like, or combinations thereof.

Bond pads 48 are formed in bond layer 46. In accordance with some embodiments, bond pads 48 are formed by etching bond layer 46 to reveal through-vias 22, filling a conductive layer(s) into the resulting openings, and performing a planarization process such as a Chemical Mechanical Polish (CMP) process or a mechanical polish process. The top surfaces of bond pads 48 and bond layer 46 are thus coplanar with each other. Bond pads 48 may include a material selected from copper, titanium, titanium nitride, tantalum, tantalum nitride, or the like. For example, each bond pad 48 may include a titanium nitride barrier layer, and a copper region on the titanium nitride barrier layer.

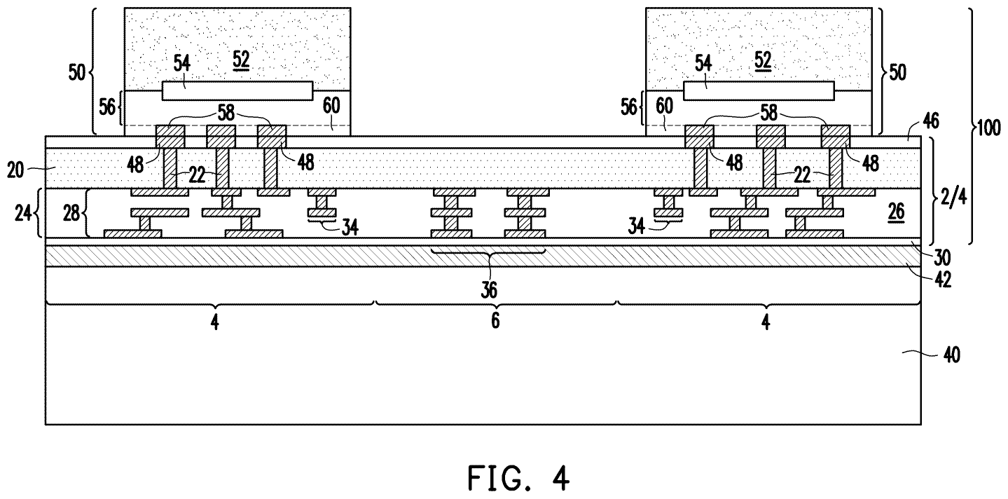

Referring to FIG. 4, device dies 50 (also referred to as top dies) are bonded to device dies 4. The respective process is illustrated as process 208 in the process flow 200 as shown in FIG. 21. The bonding may be performed through a face-to-back bonding process, with the front sides of device dies 50 being bonded to the backsides of device dies 4. In accordance with some embodiments, each of device dies 50 may be a logic die, a memory die, an IO die, an independent passive device die, or the like.

Device dies 50 may include semiconductor substrates 52, which may be silicon substrates. Device dies 50 include interconnect structures 56 for connecting to the active devices and passive devices in device dies 50. Interconnect structures 56 include metal lines and vias, as schematically illustrated.

Each of device dies 50 includes bond pads 58 and bond layer 60 (also referred to as a bond film) at the illustrated bottom surface of device die 50. The bottom surfaces of bond pads 58 may be coplanar with the bottom surface of bond layer 60. In accordance with some embodiments, bond layer 60 may be formed of a silicon-containing dielectric material, which may be selected from SiO, SiC, SiN, SiON, SiOC, SiCN, SiOCN, or the like, or combinations thereof. Bond pads 58 may comprise copper, and may be formed through a damascene process. The bond layer 60 and bond pads 58 are planarized so that their surfaces are coplanar, which may be resulted due to the CMP in the formation of bond pads 58.

The bonding may be achieved through a bonding in which bond pads 58 are bonded to bond pads 48 through metal-to-metal direct bonding, and bond layers 60 are bonded to bond layer 46 through fusion bonding. In accordance with some embodiments, the metal-to-metal direct bonding is copper-to-copper direct bonding. Furthermore, the bond layers 60 of device dies 50 are bonded to bond layer 46 of the underlying wafer 2 through fusion bonding, for example, with Si-O-Si bonds being generated. The structures over carrier 40 and layer 42 are collectively referred to as reconstructed wafer 100 hereinafter, and more features will be formed to further expand the reconstructed wafer 100 in subsequent processes.

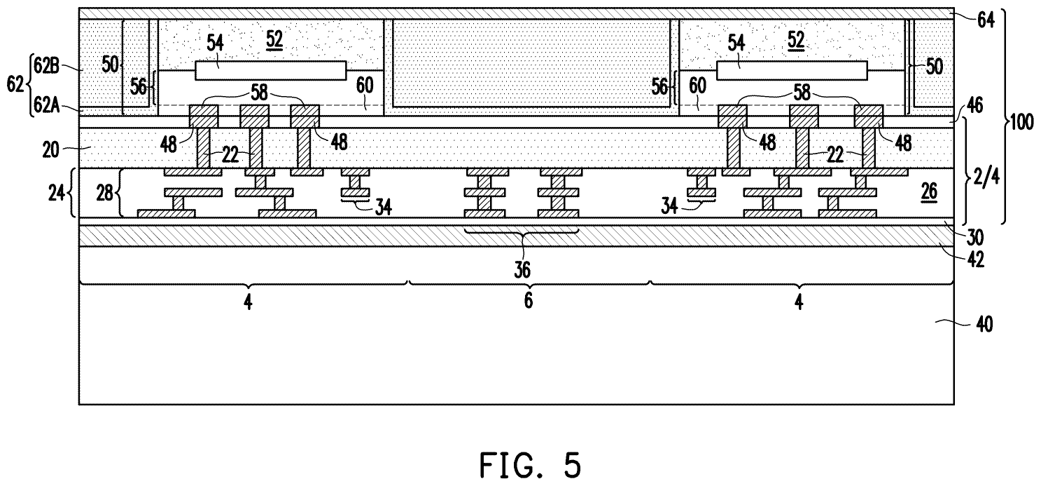

Referring to FIG. 5, a gap-filling process is performed to fill the gaps between neighboring device dies 50, and to encapsulate device dies 50 in dielectric gap-fill regions 62 (also referred to as an encapsulant). The respective process is illustrated as process 210 in the process flow 200 as shown in FIG. 21. In accordance with some embodiments, gap-fill regions 62 comprise gap-fill layer 62, which may further include a dielectric liner 62A, and a dielectric gap-fill layer 62B over the dielectric liner 62A. The dielectric liner 62A may be formed of a material that has good adhesion to device dies 50. In accordance with some embodiments, the dielectric liner 62A is formed of or comprises silicon nitride. The dielectric liner 62A is formed in a conformal deposition process, and hence is a conformal layer. The dielectric gap-fill layer 62B may be formed of an oxide-based dielectric material such as silicon oxide, silicon oxynitride, a silicate glass, or the like. The dielectric gap-fill layer 62B may also be formed through a deposition process.

In accordance with alternative embodiments, gap-fill layer 62 is formed of or comprises a molding compound, a molding underfill, or the like. The corresponding process may include dispensing a dielectric material in a flowable form, and curing the dielectric material.

After the gap-fill layer 62 is deposited, a planarization process such as a CMP process or a mechanical polish process is performed to level the back surfaces of device dies 50 with the top surfaces of the gap-fill layer 62. The remaining portions of gap-fill layer 62 are referred to as gap-fill regions 62 hereinafter.

In a subsequent process, as shown in FIG. 5, bond layer 64 is formed over device dies 50 and gap-fill regions 62. Bond layer 64 may also be formed of or comprise a silicon-containing dielectric material, which may be selected from SiO, SiC, SiN, SiON, SiOC, SiCN, SiOCN, or the like, or combinations thereof. In accordance with alternative embodiments, bond layer 64 is not formed.

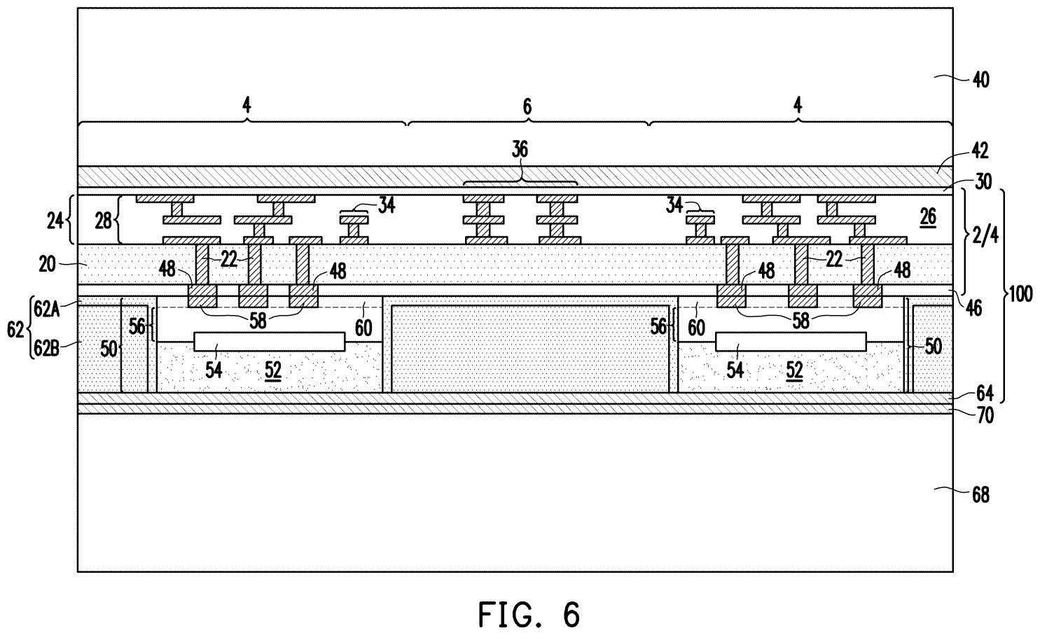

In a subsequent process, as shown in FIG. 6, reconstructed wafer 100 is attached to carrier 68. The respective process is illustrated as process 212 in the process flow 200 as shown in FIG. 21. In accordance with some embodiments, carrier 68 is left in the final structure and may be used as a supporting substrate, and possibly as a heat sink. In accordance with these embodiments, bond layer 70 may be formed on carrier 68, with the bond layer 70 being formed of a silicon-containing dielectric material selected from the same group of candidate materials of bond layer 64. The materials of bond layers 64 and 70 may be the same as each other or different from each other. The bond layer 70 is bonded with the bond layer 64 through fusion bonding.

In accordance with alternative embodiments, carrier 68 includes a transparent substrate such as a glass substrate, and layer 70 may be formed of an adhesive such as an LTHC material, which is configured to be decomposed under the heat of light (such as a laser beam).

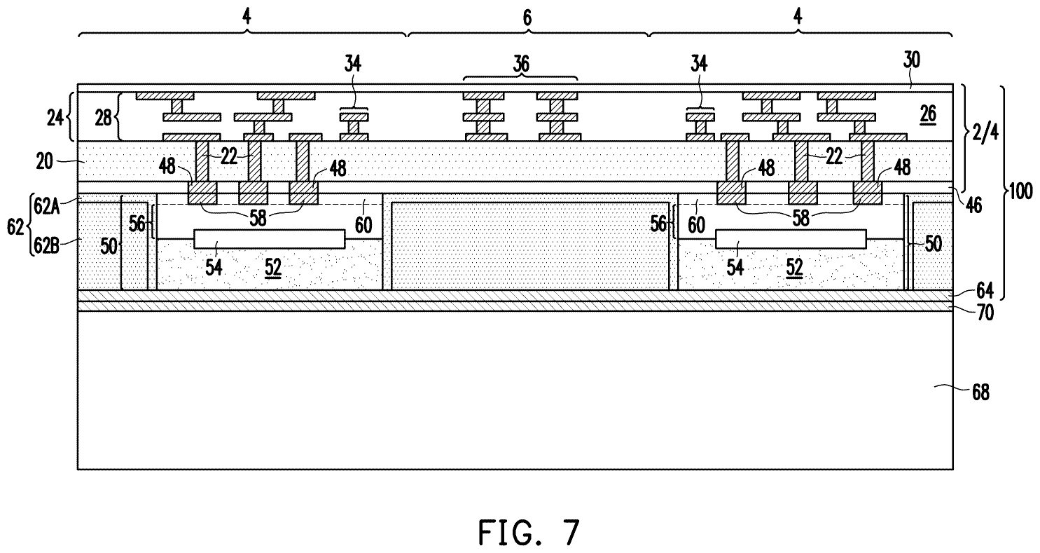

Carrier 40 is then detached, and the resulting structure is illustrated in FIG. 7. The respective process is illustrated as process 214 in the process flow 200 as shown in FIG. 21. In accordance with some embodiments in which carrier 40 comprises a silicon wafer, carrier 40 may be removed by implanting carrier 40, for example, using hydrogen to generate a stress-concentrated layer, and annealing the carrier 40, so that carrier 40 may be separated at the stress-concentrated layer. The remaining portions of carrier 40 may be removed, for example, through etching, a CMP process, or a mechanical grinding process. Layer 42, which is a bond layer in accordance with these embodiments, may also be removed.

In accordance with alternative embodiments in which carrier 40 is a glass carrier. reconstructed wafer 100 may be de-bonded from carrier 40 by projecting a laser beam onto layer 42, which may include a LTHC coating material, so that the LTHC coating material is decomposed, releasing the reconstructed wafer 100 from carrier 40.

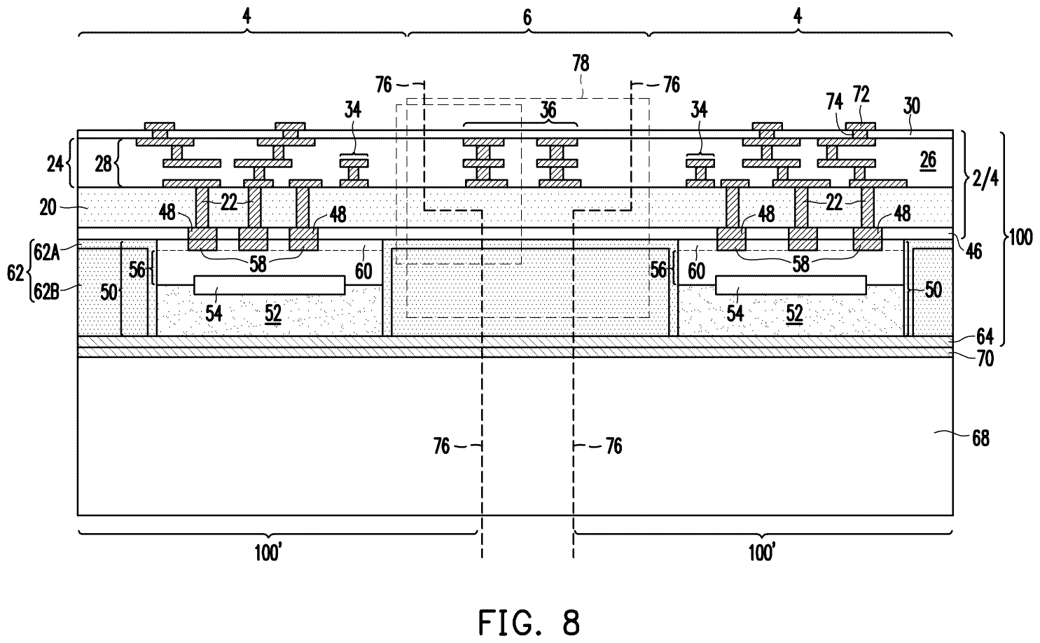

Next, as shown in FIG. 8, electrical connectors 72 are formed. Dielectric layer 30, if not formed yet, may be (or may not be) formed at this time. The respective process is illustrated as process 216 in the process flow 200 as shown in FIG. 21. Dielectric layer 30, when formed at this time, may be formed of or comprise silicon oxide, silicon nitride, silicon oxynitride, or the like. Vias 74 are formed to connect electrical connectors 72 to conductive features 28. Electrical connectors 72 may comprise solder regions, metal pillars, and/or the like.

In subsequent processes, reconstructed wafer 100 is singulated in a singulation process, so that discrete packages 100′ are formed. The discrete packages 100′ include device dies 4 and 50, and may (or may not) include the pieces of carrier 68, which may be supporting substrates. Dashed lines 76 illustrate the example positions of the surfaces (including top surfaces and edges) of packages 100′, which surfaces are generated by the singulation processes as discussed subsequently.

A singulation process of the reconstructed wafer 100 is shown in FIGS. 9A, 9B, 10A, 10B, 11A, 11B, and 12-15. The portions of the reconstructed wafer 100 as shown in FIGS. 9A and 9B through 15 are in region 78 in FIG. 8, while other portions of the reconstructed wafer 100 are not shown, and may be realized from FIG. 8.

FIG. 9A illustrates a cross-sectional view of the region 78 as shown in FIG. 8. The dummy features 36 (FIG. 8, if any) are not shown, although they also exist in peripheral region P1. FIG. 9B illustrates a top view of a portion of wafer 2, wherein the cross-sectional view as shown in FIG. 9A may be obtained from the cross-sections 9A-9A in FIG. 9B.

As shown in FIG. 9A, scribe line 6 includes peripheral region P1 in the middle of scribe line 6, and peripheral regions P2 on opposite sides of the peripheral region P1. Each of the peripheral regions P1 and P2 may be a strip-shaped region (as shown in FIG. 9B) extending from one side of wafer 2 (which may have a rounded top-view shape) to the opposite side. The peripheral regions P1 are the regions in which wide blade sawing processes are to be performed. The peripheral regions P2 are the regions in which narrower laser grooving processes are to be performed. Defocusing laser processes (as discussed subsequently) may or may not be performed, and if performed, are also performed in peripheral regions P2.

Referring again to FIG. 9A, first narrow laser grooving processes are performed, each in one of peripheral regions P2. The respective process is illustrated as process 218 in the process flow 200 as shown in FIG. 21. In each of the narrow laser grooving processes, the laser beam 80 is scanned in X-direction (FIG. 9B) and also in Y-direction, and from one end of wafer to the opposite end in each laser scanning.

Laser beam 80 is illustrated as having a tapered profile, with the middle portion being illustrated as extending lower than edge portions. In reality, laser beam 80 has a uniform width from the exit point of the laser beam generator (not shown) to where it lands on wafer 2. On the other hand, the power density of a laser beam 80 may have a distribution (such as a gaussian distribution) with the center portion having the highest power, and the edge portions having increasingly lower power density. Profiles 82 are illustrated to show an example power density distribution profile, wherein the lower portions of profiles 82 representing higher power density values, and vice versa. Since the parts of the laser beam 80 having higher power density may cause deeper grooves than the parts of the laser beam 80 having lower power density, when the laser beam 80 having the power density profile 82 is projected on wafer 2, the resulting grooves will also have the profile with the center portions deeper than edge portions. Laser beam 80 is thus drawn as having a tapered shape to reflect the shape of the resulting grooves.

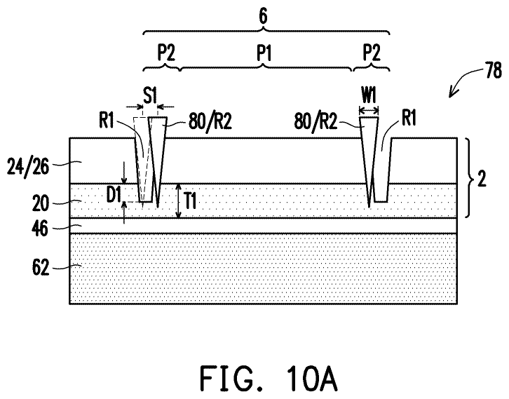

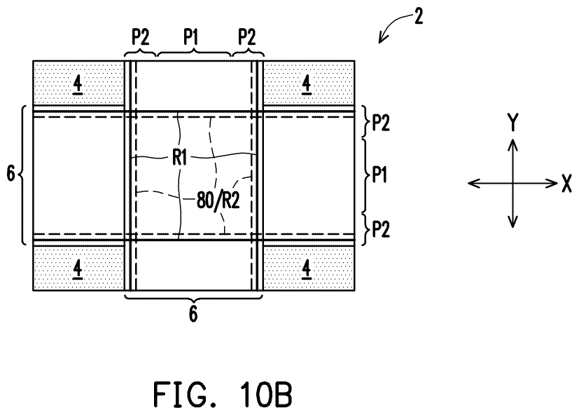

The first narrower laser grooving process may form grooves R1 as shown in FIG. 10A. Throughout the description, the terms “groove” and “recess” are used interchangeably. grooves R1 penetrate through interconnect structure 24 (and dielectric layers 26) and extend into semiconductor substrate 20. In accordance with some embodiments, the extending depth D1 into semiconductor substrate 20 is smaller than 50 percent of the thickness T1 of semiconductor substrate 20. Depth D1 may also be greater than about 1.5 μm to ensure the overlying interconnect structure 24 is removed or substantially removed. For example, thickness T1 may be in the range between about 3 μm and about 7 μm, and hence depth D1 may be in the range between about 1.5 μm and about 3 μm. The width W1 of the grooves R1 (FIG. 9A) may be in the range between about 2 μm and about 4 μm.

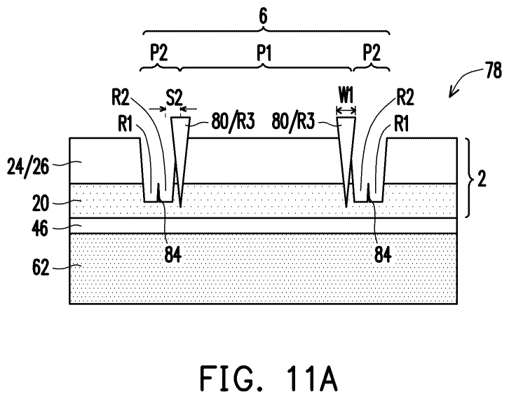

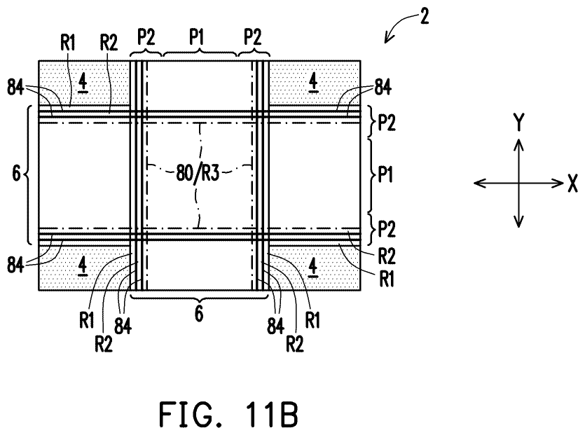

Next, as shown in FIGS. 10A and 10B, which illustrates a cross-sectional view and a top view, respectively, a second plurality of narrow laser grooving processes are performed in peripheral regions P2, for example, using laser beam 80 also. The respective process is illustrated as process 220 in the process flow 200 as shown in FIG. 21. The second plurality of narrow laser grooving processes are performed at positions shifted away from the positions of the first plurality of narrow laser grooving processes. The shifting distance S1 is smaller than the width W1 of the grooves R1. The ratio S1/W1 may be in the range between about 0.2 and about 0.9. A second plurality of grooves R2 are thus formed, as shown in FIGS. 11A and 11B. The grooves R2 partially overlap the corresponding nearest grooves R1.

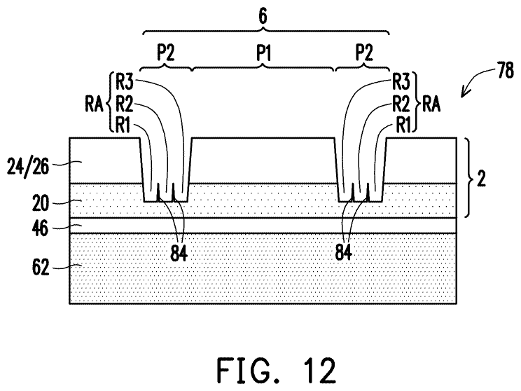

FIGS. 11A and 11B further illustrate a third plurality of narrow laser grooving processes performed in peripheral regions P2, for example, using laser beam 80 also. The respective process is illustrated as process 222 in the process flow 200 as shown in FIG. 21. The third plurality of narrow laser grooving processes are performed at positions that are further shifted away from the positions of the second plurality of narrow laser grooving processes. The shifting distance S2 is also smaller than the width W1 of the grooves R1. The ratio S2/W1 may be in the range between about 0.2 and about 0.9. A third plurality of grooves R3 are thus formed, as shown in FIG. 12. The grooves R3 partially overlap the corresponding grooves R2, and may or may not overlap grooves R1.

In accordance with some embodiments, there are three narrow laser grooving processes performed in each of peripheral region P2. In accordance with alternative embodiments, there are two narrow laser grooving processes performed in each of peripheral region P2, and hence the third plurality of laser grooving processes are not performed. In accordance with yet alternative embodiments, there may be 4, 5, 6, or more narrow laser grooving processes performed in each of peripheral region P2, each partially shifted relative to other nearest ones.

The grooves R1, R2, and R3 in the same peripheral region P2 are joined to form a combined groove (recess) RA. Since grooves R1, R2, and R3 are tapered, the upper portions of grooves R1, R2, and R3 are joined. The lower portions of grooves R1, R2, and R3 may be separated from each other by residue portions 84 of wafer 2, which residue portions may include some portions of semiconductor substrate 20, and may or may not include the residue portions of dielectric layers 26.

Since the profiles of grooves R1, R2, and R3 are tapered, the residue portions 84 are also tapered, with upper portions narrower than the respective lower portions. The top surfaces of semiconductor substrate 20 (under recesses R1, R2, and R3) between the residue portions 84 may be planar, rounded, or may have irregular shapes.

As shown in FIG. 11B, in a top view of wafer 2, residue portions 84 may also have strip shapes, which may extend from the left edge (in the X-direction) of wafer 2 to the right edge of wafer 2, and from the top edge (in the Y-direction of the top view) to the bottom edge of wafer 2. The resulting cross-sectional view after the third narrower laser grooving processes is shown in FIG. 12.

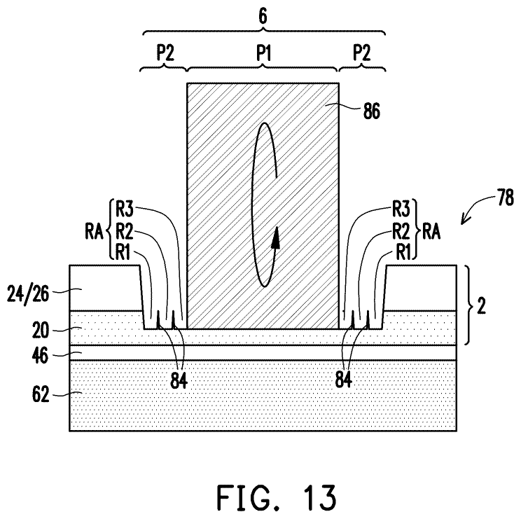

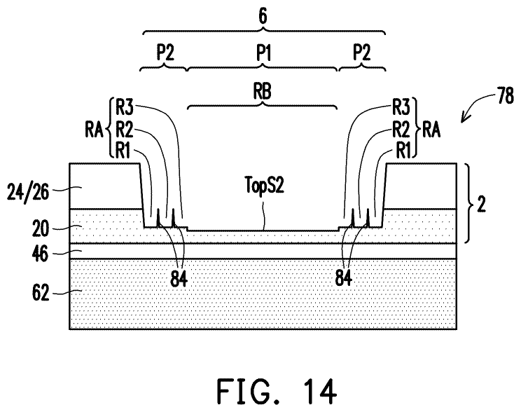

Referring to FIG. 13, a wide blade sawing (grooving) process is performed using blade 86, which is used to saw the portion of wafer 2 in peripheral region P1 (and possibly parts of the peripheral regions P2). The respective process is illustrated as process 224 in the process flow 200 as shown in FIG. 21. Blade 86 also extends slightly into combined groove RA, so that the portions of the interconnect structures 24 between opposing combined grooves RA (FIG. 12) are fully removed. Blade 86 has the capability of removing metal, so that the dummy conductive features 36 (FIG. 8), if formed, are also removed. In accordance with alternative embodiments, the wide grooving process to form groove RB (FIG. 14) is performed through another method such as etching.

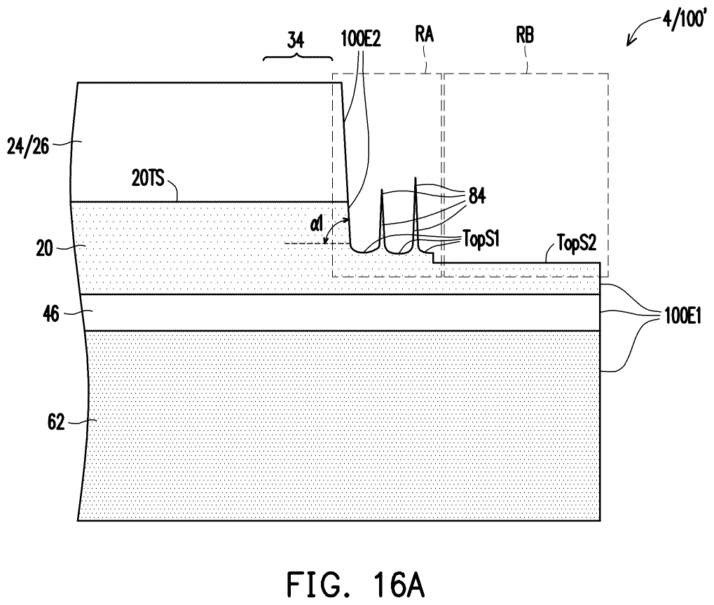

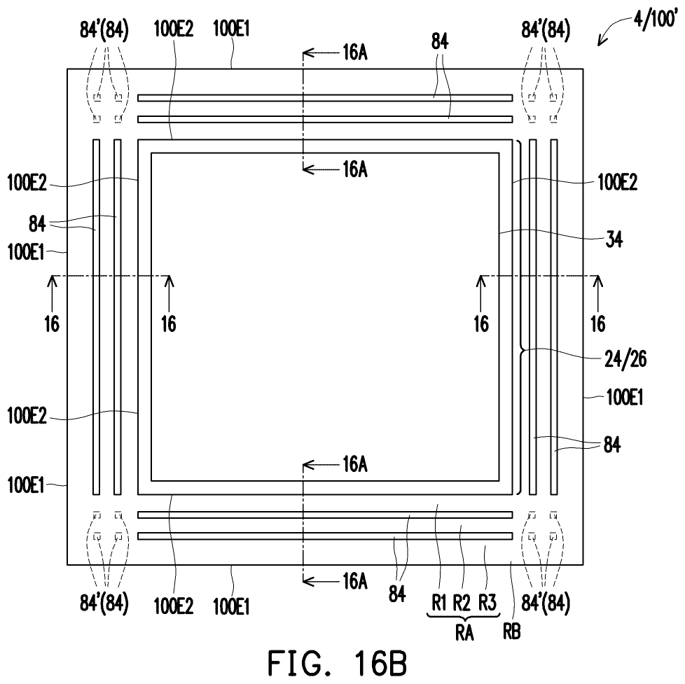

FIG. 14 illustrates the wafer 2 after the wide blade sawing process. Blade 86 cuts into semiconductor substrate 20, and does not cut through semiconductor substrate 20. Accordingly, the top surface TopS2 of semiconductor substrate 20 is generated by the wide blade sawing process. The top surface TopS2 may be planar or having other cross-sectional shapes such as a V-shape, a curved shape, or the like, depending on the blade 86. The top surface TopS2, for example, when having the V-shape, may be straight and tilted. The top surfaces TopS1 (FIG. 16) as generated by the narrow laser grooving processes, on the other hand, may be irregular or may be curved.

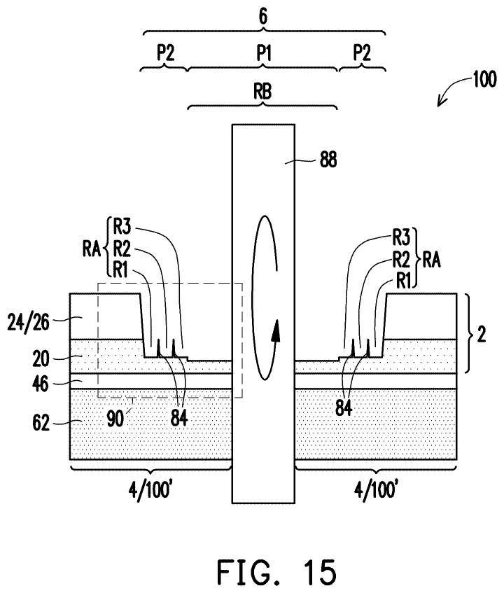

Referring to FIG. 15, a narrow blade sawing process is performed using blade 88, which is used to saw wafer 2 in peripheral regions P1. The reconstructed wafer 100 is thus sawed as discrete packages 100′, which includes device dies 4 and 50 (FIG. 8) therein. The respective process is illustrated as process 226 in the process flow 200 as shown in FIG. 21. Blade 88 is run inside peripheral region P1, so that blade 88 does not physically touch interconnect structure 24 and dielectric layers 26. It is appreciated that if blade 88 physically contacts dielectric layers 26 during the narrow blade sawing process, the physical force introduced by the blade 88 may tear dielectric layers 26, and delamination may occur between the dielectric layers 26 and the semiconductor substrate 20.

If one narrow laser grooving process is performed in each peripheral region P2 to form groove R1, the width of the groove R1 is small and does not allow enough process margin. A laser grooving process may have to be used to remove dielectric layers 26 from peripheral regions P1 using a high energy wide laser beam. It is, however, difficult to control the high-energy wide laser beam grooving process and to remove all dielectric layers in peripheral regions P1, without the concern of over-grooving (and grooving through) semiconductor substrate 20.

In accordance with the embodiments of the present disclosure, by performing multiple narrow grooving processes, the combined grooves RA are widened, and adequate process margin is generated, so that a wide blade sawing process (using blade 86, FIG. 13) may be performed, which has the capability to accurately remove dielectric layer 26 fully, but does not cut through semiconductor substrate 20.

FIG. 16A illustrates the edge portion of device die 4 after the narrow blade sawing process, wherein the edge portion is in region 90 in FIG. 15. Device die 4 includes combined groove RA generated by the narrow laser grooving processes, and the groove RB generated by the wide blade sawing process. Residue portions 84 are in the combined groove RA, and may or may not include dielectric layers 26. The topmost ends of the residue portions 84 may be higher than, level with, or lower than top surface 20TS of semiconductor substrate 20, which top surface 20TS also forms an interface with the overlying dielectric layers 26. In FIG. 16A, top surface TopS2 may be lower than, level with, or higher than top surfaces TopS1. The Residue portions 84 are in the extension portions of the semiconductor substrate 20 that extend beyond edge 100E2.

Due to the laser grooving process, the edge 100E2 is slanted, and may be straight. The tilt angle α1 may be in the range between about 80 degrees and about 88 degrees in accordance with some embodiments.

FIG. 16B illustrates a top view of package 100′ in accordance with some

embodiments, wherein the cross-sectional view shown in FIG. 16A may be obtained from the cross-sections 16A-16A in FIG. 16B. When viewed in the top view, the residue portions 84 may have lengthwise directions parallel to the edges 100E1 of package 100′. Each edge portions of device die 4 has one or more strip-shaped residue portions 84 parallel to the corresponding edges 100E1. The residue portions 84 parallel to different edges 100E1 are physically disconnected from each other. Some residue portions 84 (marked as 84′) may also be formed as discrete portions that are not elongated. In FIG. 16B, the portion of the package 100′ beyond edges 100E1 are referred to as extension portions.

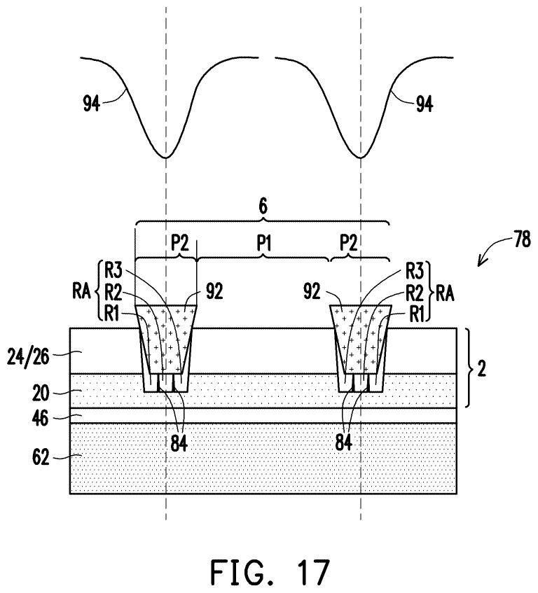

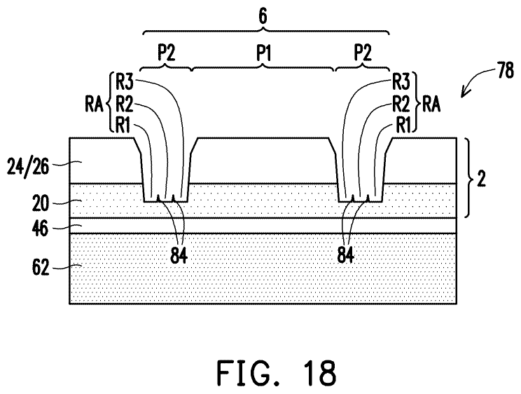

FIGS. 17 and 18 illustrate the intermediate stages in the formation of the package 100′ in accordance with alternative embodiments. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

The initial processes of these embodiments are essentially the same as shown in FIGS. 1 through 12. Next, as shown in FIG. 17, a defocus laser cleaning process is performed using a defocusing laser beam 92 to remove the residue portions 84 in the peripheral region P2. The defocusing laser beam 92 may defocus from the top surface of wafer 2 and may defocus from the surface of semiconductor substrate 20, in order to widen the laser beam and to reduce the irradiation energy. As a result, the residue portions 84 may be removed or reduced, while the semiconductor substrate 20 is not further grooved. In accordance with some embodiments, the focus of laser beam 92 may be at a position higher than the top surface of wafer 2, for example, by a height difference in a range between about 200 μm and about 400 μm. Profile 94 illustrates the power density of layer beam 92 in accordance with some embodiments. FIG. 18 illustrates a resulting structure.

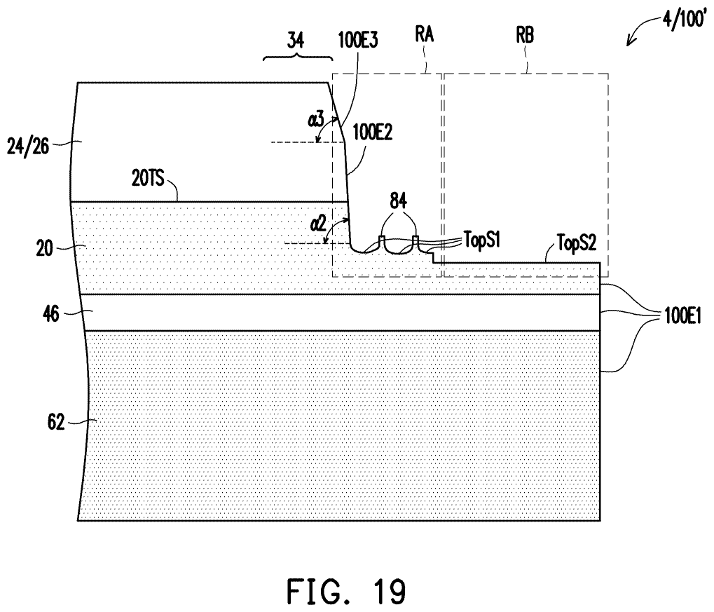

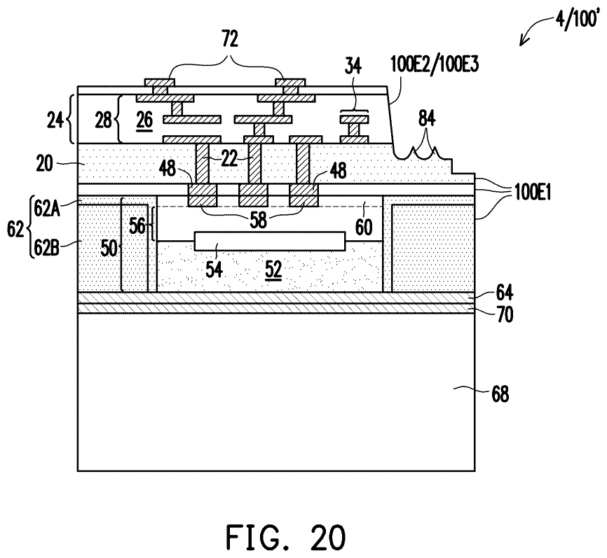

Subsequent to the defocus laser cleaning process, the processes as shown in FIGS. 13-15 are performed. FIG. 19 illustrates a resulting package 100′. While residue portions 84 have some portion remaining as shown in FIG. 19, the residue portions 84 may also be fully removed. Due to the laser grooving process, the edge 100E2 is slanted, and may be straight. The tilt angle α1 may be in the range between about 80 degrees and about 88 degrees in accordance with some embodiments. The defocus laser cleaning process also results edge 100E3 to be formed as a slant edge, which has tilt angle α2 greater than tilt angle α1. Tilt angle α2 may be in the range between about 75 degrees and about 85 degrees. The difference (α2−α1) may be greater than about 5 degrees, and may be in the range between about 5 degrees and about 10 degrees.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By performing a plurality of narrow laser grooving processes with the laser paths partially overlapping, the width of the resulting combined groove is increased. This enables the adoption of a wide sawing process to be performed using a blade, without the concern of tearing the dielectric layers by the blade. The accuracy of the wide sawing/grooving process is thus improved, so that the wide sawing/grooving process may stop on, and does not penetrate through, the semiconductor substrate.

In accordance with some embodiments of the present disclosure, a method comprises performing a first plurality of laser grooving processes on a scribe line of a substrate to form a first combined groove; performing a second plurality of laser grooving processes on the scribe line of the substrate to form a second combined groove; performing a first sawing process on the scribe line of the substrate, wherein the first sawing process is performed in a part of the scribe line between the first combined groove and the second combined groove; and performing a second sawing process to saw through the substrate in the scribe line, wherein the second sawing process separates a first device die and a second device die on opposing sides of the scribe line from each other.

In an embodiment, the first plurality of laser grooving processes comprise a first grooving process along a first path in the scribe line; and a second grooving process along a second path in the scribe line, wherein the second path partially overlaps the first path. In an embodiment, the first plurality of laser grooving processes further comprise a third grooving process along a third path in the scribe line, wherein third second path partially overlaps the second path. In an embodiment, the first combined groove is wider than a single groove that is generated by a single grooving process comprised in the first plurality of laser grooving processes.

In an embodiment, the first sawing process generates a third groove that joins the first combined groove to the second combined groove. In an embodiment, the first sawing process is stopped after a semiconductor substrate of the substrate is exposed, and before the semiconductor substrate is sawed through. In an embodiment, the first sawing process is performed using a blade. In an embodiment, the method further comprises performing a defocus laser grooving process on the first combined groove.

In an embodiment, the first combined groove extends into a semiconductor substrate of the substrate, and at least a residue portion of semiconductor substrate is under the first combined groove and between two of grooves that are generated by two of the plurality of grooving processes. In an embodiment, after the second sawing process, the first device die comprises a portion of the first combined groove.

In accordance with some embodiments of the present disclosure, a structure comprises a first device die comprising a semiconductor substrate, wherein the semiconductor substrate comprises a first edge and a second edge laterally recessed from the first edge, wherein the second edge has at least a portion higher than the first edge; a first top surface laterally between the first edge and the second edge; and a first part protruding higher than the first top surface, wherein the first part is also laterally between the first edge and the second edge.

In an embodiment, the first part is tapered, and comprises lower portions and upper portions, and wherein the upper portions are narrower than respective ones of the lower portions. In an embodiment, the first device die further comprises a plurality of dielectric layers over the semiconductor substrate, and wherein the first part further comprises a part of the plurality of dielectric layers. In an embodiment, the semiconductor substrate comprises a planar top surface joined to the second edge, and wherein a topmost end of the first part is lower than the planar top surface.

In an embodiment, the first top surface of the semiconductor substrate is joined to the first edge, and wherein the semiconductor substrate further comprises a second top surface joined to a bottom of the first part, and wherein the first top surface and the second top surface are at different levels. In an embodiment, the first top surface of the semiconductor substrate is joined to the first edge, and is planar, and wherein the second top surface is non-planar. In an embodiment, the structure further comprises a second device die underlying and electrically connected to the first device die; and gap-fill regions on opposing sides of the second device die, wherein the gap-fill regions comprise an additional edge vertically aligned to the first edge of the semiconductor substrate.

In accordance with some embodiments of the present disclosure, a structure comprises a device die comprising a plurality of dielectric layers; and a semiconductor substrate underlying the plurality of dielectric layers, wherein the semiconductor substrate comprises a first top surface underlying and contacting the plurality of dielectric layers; and a first extension portion laterally extending beyond a first edge of the plurality of dielectric layers, wherein the first extension portion comprises a second top surface lower than the first top surface; and a first residue portion protruding higher than the second top surface, wherein in a top view of the structure, the first part has a strip shape, with a first lengthwise direction of the first part being parallel to the first edge of the plurality of dielectric layers.

In an embodiment, the semiconductor substrate further comprises a second extension portion extending laterally beyond a second edge of the plurality of dielectric layers, wherein the second extension portion comprises a third top surface lower than the first top surface; and a second part protruding higher than the third top surface, wherein in the top view of the structure, the second part has a second lengthwise direction being perpendicular to the first lengthwise direction. In an embodiment, the first extension portion further comprises an additional part protruding higher than the second top surface, wherein in the top view of the structure, the additional part is parallel to the first part.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
performing a first plurality of laser grooving processes on a scribe line of a substrate to form a first combined groove;
performing a second plurality of laser grooving processes on the scribe line of the substrate to form a second combined groove;
performing a first sawing process on the scribe line of the substrate, wherein the first sawing process is performed in a part of the scribe line between the first combined groove and the second combined groove; and
performing a second sawing process to saw through the substrate in the scribe line, wherein the second sawing process separates a first device die and a second device die on opposing sides of the scribe line from each other.

2. The method of claim 1, wherein the first plurality of laser grooving processes comprise:
a first grooving process along a first path in the scribe line; and
a second grooving process along a second path in the scribe line, wherein the second path partially overlaps the first path.

3. The method of claim 2, wherein the first plurality of laser grooving processes further comprise:
a third grooving process along a third path in the scribe line, wherein third second path partially overlaps the second path.

4. The method of claim 1, wherein the first combined groove is wider than a single groove that is generated by a single grooving process comprised in the first plurality of laser grooving processes.

5. The method of claim 1, wherein the first sawing process generates a third groove that joins the first combined groove to the second combined groove.

6. The method of claim 1, wherein the first sawing process is stopped after a semiconductor substrate of the substrate is exposed, and before the semiconductor substrate is sawed through.

7. The method of claim 1, wherein the first sawing process is performed using a blade.

8. The method of claim 1 further comprising performing a defocus laser grooving process on the first combined groove.

9. The method of claim 1, wherein the first combined groove extends into a semiconductor substrate of the substrate, and at least a residue portion of semiconductor substrate is under the first combined groove and between two of grooves that are generated by two of the plurality of grooving processes.

10. The method of claim 1, wherein after the second sawing process, the first device die comprises a portion of the first combined groove.

11. A structure comprising:
a first device die comprising a semiconductor substrate, wherein the semiconductor substrate comprises:
a first edge and a second edge laterally recessed from the first edge, wherein the second edge has at least a portion higher than the first edge;
a first top surface laterally between the first edge and the second edge; and
a first residue portion protruding higher than the first top surface, wherein the first residue portion is also laterally between the first edge and the second edge.

12. The structure of claim 11, wherein the first residue portion is tapered, and comprises lower portions and upper portions, and wherein the upper portions are narrower than respective ones of the lower portions.

13. The structure of claim 11, wherein the first device die further comprises a plurality of dielectric layers over the semiconductor substrate, and wherein the first residue portion further comprises a part of the plurality of dielectric layers.

14. The structure of claim 11, wherein the semiconductor substrate comprises a planar top surface joined to the second edge, and wherein a topmost end of the first residue portion is lower than the planar top surface.

15. The structure of claim 11, wherein the first top surface of the semiconductor substrate is joined to the first edge, and wherein the semiconductor substrate further comprises a second top surface joined to a bottom of the first residue portion, and wherein the first top surface and the second top surface are at different levels.

16. The structure of claim 15, wherein the first top surface of the semiconductor substrate is joined to the first edge, and is planar, and wherein the second top surface is non-planar.

17. The structure of claim 11 further comprising:
a second device die underlying and electrically connected to the first device die; and
gap-fill regions on opposing sides of the second device die, wherein the gap-fill regions comprise an additional edge vertically aligned to the first edge of the semiconductor substrate.

18. A structure comprising:
a device die comprising:
a plurality of dielectric layers; and
a semiconductor substrate underlying the plurality of dielectric layers, wherein the semiconductor substrate comprises:
a first top surface underlying and contacting the plurality of dielectric layers; and
a first extension portion laterally extending beyond a first edge of the plurality of dielectric layers, wherein the first extension portion comprises:
a second top surface lower than the first top surface; and
a first part protruding higher than the second top surface, wherein in a top view of the structure, the first part has a strip shape, with a first lengthwise direction of the first part being substantially parallel to the first edge of the plurality of dielectric layers.

19. The structure of claim 18, wherein the semiconductor substrate further comprises a second extension portion extending laterally beyond a second edge of the plurality of dielectric layers, wherein the second extension portion comprises:
a third top surface lower than the first top surface; and
a second part protruding higher than the third top surface, wherein in the top view of the structure, the second part has a second lengthwise direction being perpendicular to the first lengthwise direction.

20. The structure of claim 18, wherein the first extension portion further comprises:
an additional part protruding higher than the second top surface, wherein in the top view of the structure, the additional part is parallel to the first part.
